(19) United States
(12) Patent Application Publication
(10) Pub. No.: US 2012/0326527 A1
(43) Pub. Date: Dec. 27, 2012

(54) ELECTROMAGNETIC PULSE GENERATOR

(76) Inventors: Miron Tuval, Ramat-Gan (IL); Asher Yahalom, Givaat-Shmuel (IL)

(21) Appl. No.: 13/576,183

(22) PCT Filed: Jan. 30, 2011
(86) PCT No.: PCT/IB11/50404

§ 371 Date: Sep. 4, 2012

Related U.S. Application Data
(60) Provisional application No. 61/299,981, filed on Jan. 31, 2010.

(51) Int. Cl. H03K 3/02

(52) U.S. Cl. 307/106

(57) ABSTRACT

An electromagnetic pulse generating apparatus including an elongated flexible tube having an inflated mode and a non-inflated mode, wherein a cross section of said tube perpendicular to the elongation axis is larger when inflated mode than when not-inflated. The tube is placed inside an electrically conductive coil wound along the elongated axis and electrically connected to an output connector, and an opening connected to a source of a hydraulic and/or pneumatic pressure. A magnetic field generating apparatus provides a magnetic flux parallel to coil axis. Where the tube is operative to receive the pressure into the opening, causing the tube to inflate, thus causing change of cross-section area of the coil within the magnetic flux, thus generating an electromagnetic pulse at the output connector.

### CROSS-REFERENCE TO RELATED APPLICATIONS

This application claims priority benefit from U.S. Provisional Patent Application No. 61/299,981, filed Jan. 31, 2010, which is incorporated herein by reference in its entirety.

### FIELD AND BACKGROUND OF THE INVENTION

The present invention relates to systems and method for generating an electromagnetic pulse, and, more particularly, but not exclusively to high power electromagnetic pulse systems and/or Flux Compression Generator (FCG).

The following document is believed to represent the most relevant prior art:

Compact High Power Microwave, by A. Neuber, A. Young, M. Elsayed, J. Dickens, M. Giesselmann, M. Kristiansen, Center for Pulsed Power & Power Electronics, Department of Electrical & Computer Engineering, Texas Tech University, Box 43102, Lubbock, Tex. 79409-3102 and L. L. Altgilbers US Army Forces Strategic Command, SMDC-RDTC-TDA, P.O. Box 1500, Huntsville, Ala. 35807 published in the proceedings of the Army Science Conference 2008 and available at: http://www.asc2008.com/manuscripts/D/DO-03.pdf. This document is incorporated herein by reference.

It is believed that U.S. Pat. Nos. 5,125,104, and 6,005,305 are also relevant.

High-power electromagnetic pulse generator transmits a pulse of high energy electromagnetic radiation (e.g. radio waves) preferably directed at a target. Electromagnetic pulse energy can be used for various applications such as material research, healthcare, military (causing permanent damage or temporary failure) to electronic equipment, testing (of electronic equipment or mechanical structures), etc.

The prior art use explosives to explode an armature inside a coil placed in a magnetic field, thus creating a pulse of electromagnetic energy. The use of an “explosive coil” suggests that the device and method for producing electromagnetic pulse energy is of a “single action” nature and therefore incapable of repetitive action.

There is thus a widely recognized need for, and it would be highly advantageous to have, an electromagnetic pulse generator devoid of the above limitations.

### SUMMARY OF THE INVENTION

According to one aspect of the present invention there is provided an electromagnetic pulse generating apparatus including: a flexible tube elongated along a first axis, the tube having an inflated mode and a non-inflated mode, where a cross section of the tube perpendicular to the first axis is larger in the inflated mode than in the non-inflated mode, where the tube includes an electrically conductive coil wound along the first axis and electrically connected to an output connector; and where the tube includes an opening connected to a source of at least one of a hydraulic and pneumatic pressure; a magnetic field generating apparatus providing magnetic flux, where the tube is operative to receive the at least one of a hydraulic and pneumatic pressure into the opening, the pressure causing the tube to inflate, the inflation causing change of cross-section area of the coil within the magnetic flux, thus generating the electromagnetic pulse at the output connector.

According to another aspect of the present invention there is provided an electromagnetic pulse generating apparatus including: a flexible tube elongated along a first axis, the tube having an inflated mode and a non-inflated mode, where a cross section of the tube perpendicular to the first axis is larger in the inflated mode than in the non-inflated mode, where the tube includes an electrically conductive material, and where the tube includes an opening connected to a source of at least one of a hydraulic and pneumatic pressure; a magnetic field generating apparatus providing magnetic flux; and an electrically conductive collector coil wound along the first axis and electrically connected to an output connector; where the tube is operative to receive the at least one of a hydraulic and pneumatic pressure into the opening, the pressure causing the tube to inflate, the inflation causing change of cross-section area of the coil within the magnetic flux, thus generating the electromagnetic pulse at the collector coil.

According to still another aspect of the present invention there is provided an electromagnetic pulse generating apparatus where the magnetic field is one of: at least partially perpendicular to at least one of the first axis and a direction in which the change of area of the tube is maximal; and at least partially perpendicular to the first axis.

Further according to another aspect of the present invention there is provided an electromagnetic pulse generating apparatus including a plurality of the flexible tubes.

Still further according to another aspect of the present invention there is provided an electromagnetic pulse generating apparatus where the plurality of tubes including a plurality of coils connected to a common output connector in at least one of serial and parallel.

Even further according to another aspect of the present invention there is provided an electromagnetic pulse generating apparatus where the flexible tube in the non-inflated mode is flat.

Additionally according to another aspect of the present invention there is provided an electromagnetic pulse generating apparatus where the cross-section of the flexible tube in the non-inflated mode forms the shape of an ellipse.

Also according to another aspect of the present invention there is provided an electromagnetic pulse generating apparatus where the cross-section of the flexible tube in the inflated mode forms the shape of a circle.

According to still another aspect of the present invention there is provided an electromagnetic pulse generating apparatus where the magnetic field generating apparatus is at least one of a magnet and an electromagnet.

Further according to another aspect of the present invention there is provided an electromagnetic pulse generating apparatus where the flexible tube includes at least one of Nitinol; a Nickel-Titanium composite: a shape memory alloy: and a super-elastic material.

Still further according to another aspect of the present invention there is provided an electromagnetic pulse generating system including: an electromagnetic pulse generating apparatus and a pressure pulse generating apparatus, where the output pressure connector of the pressure pulse generating apparatus is connected to the opening of the flexible tube of the electromagnetic pulse generating apparatus.

Even further according to another aspect of the present invention there is provided an electromagnetic pulse generating system where the electromagnetic pulse generating apparatus includes a plurality of the flexible tubes and where the pressure pulse generating apparatus is connected to the plurality of flexible tubes via a manifold.

Additionally according to another aspect of the present invention there is provided an electromagnetic pulse generating system and operative to deliver the pressure pulse to a selectable flexible tube.

Also according to another aspect of the present invention there is provided an electromagnetic pulse generating system operative to deliver the pressure pulse simultaneously to a selectable group of flexible tubes.

According to still another aspect of the present invention there is provided an electromagnetic pulse generating system including: a first electrically conductive coil operative to generate a magnetic field, a housing placed within the first electrically conductive coil, a second electrically conductive coil placed within the housing and operative to collect an electromagnetic pulse, a reaction barrel including electrically conductive material, placed within the second electrically conductive coil, and operative to expand responsive to internal pressure, and to retract responsive to depletion of the internal pressure, an explosive material placed within the reaction barrel, and an igniter placed within the explosive material, where the igniter is operative to detonate the explosive material; the explosive material producing a pulse of pressure; the pulse of pressure expanding the reaction barrel; the reaction barrel producing an electromagnetic pulse; the second electrically conductive collecting the electromagnetic pulse.

Further according to another aspect of the present invention there is provided an electromagnetic pulse generating system where the reaction barrel includes an opening for releasing the pulse pressure,

Still further according to another aspect of the present invention there is provided an electromagnetic pulse generating system where the opening for releasing the pulse pressure includes a stricture.

Even further according to another aspect of the present invention there is provided an electromagnetic pulse generating system where the explosive material is contained in a cartridge.

Additionally according to another aspect of the present invention there is provided an electromagnetic pulse generating system where the barrel and the cartridge are operative to enable replacement of the cartridge.

Also according to another aspect of the present invention there is provided an electromagnetic pulse generating system where the igniter is placed along the explosive material.

According to still another aspect of the present invention there is provided an electromagnetic pulse generating system where at least two of the first electrically conductive coil, housing, second electrically conductive coil, reaction barrel, explosive material, and igniter are placed concentrically.

Further according to another aspect of the present invention there is provided an electromagnetic pulse generating system where the explosive material includes aluminum and water.

Still further according to another aspect of the present invention there is provided an electromagnetic pulse generating system where the output connector is connected to the first electrically conductive coil and operative to generate a pulse of magnetic field.

Unless otherwise defined, all technical and scientific terms used herein have the same meaning as commonly understood by one of ordinary skill in the art to which this invention belongs. The materials, methods, and examples provided herein are illustrative only and not intended to be limiting. Except to the extent necessary or inherent in the processes themselves, no particular order to steps or stages of methods and processes described in this disclosure, including the figures, is intended or implied. In many cases the order of process steps may vary without changing the purpose or effect of the methods described.

Implementation of the method and system of the present invention involves performing or completing certain selected tasks or steps manually, automatically, or any combination thereof. Moreover, according to actual instrumentation and equipment of preferred embodiments of the method and system of the present invention, several selected steps could be implemented by hardware or by software on any operating system of any firmware or any combination thereof. For example, as hardware, selected steps of the invention could be implemented as a chip or a circuit. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a simplified block diagram of an electromagnetic pulse generator;

FIGS. 2A, 2B, 2C and 2D are, respectively, simplified illustrations of: output (rear), input (front), side and perspective views of an open-ended tubular coil in a relaxed (or deflated) mode;

FIGS. 3A, 3B, 3C and 3D are, respectively, simplified illustrations of: output (rear), input (front), side and perspective views of an open-ended tubular coil 18 in an inflated mode

FIGS. 4A, 4B, 4C, 4D are simplified illustrations of different views of a closed-ended tubular coil;

FIGS. 5A, 5B, 5C, 5D are simplified illustrations of different views of a flat tubular coil;

FIGS. 6A and 6B are simplified illustrations of a side view and a front view, respectively, of the tubular coil placed in a magnetic field generated by a fixed magnet magnetic field generating device;

FIG. 7 is a simplified illustrations of a side view of the tubular coil placed in a magnetic field generated by an electromagnet magnetic field generating device;

FIGS. 8A, 8B and 8C are simplified schematic illustrations of an electromagnetic pulse generating device;

FIG. 9 is a simplified illustration of a side view of an electromagnetic pulse generation system;

FIG. 10 is a simplified illustration of a side view of a multi-coil electromagnetic pulse generator;

FIG. 11, which is a simplified illustration of a side view of a separately-operated multi-coil electromagnetic pulse generator;

FIG. 12, which is a simplified illustration of a side view of an electromagnetic pulse generator system including both fixed magnet and electromagnet magnetic field generating devices;

FIG. 13 is a simplified schematic illustration of an explosive electromagnetic pulse-generating device;

FIG. 14 is a simplified schematic illustration of a detail of the explosive electromagnetic pulse-generating device; and

FIG. 15 is a simplified schematic illustration of an explosive pulse generating system.

### DETAILED DESCRIPTION OF THE INVENTION

The principles and operation of a system and a method for generating a pulse of high-power electromagnetic radiation. According to the present invention may be better understood with reference to the drawings and accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

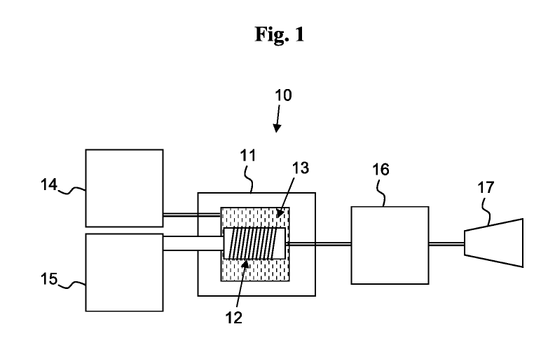

Reference is now made to FIG. 1, which is a simplified block diagram of an electromagnetic pulse generator 10 according to a preferred embodiment of the present invention.

Typically, the electromagnetic pulse generator 10 transmits a pulse of high energy electromagnetic radiation (e.g. radio waves) preferably directed at a target. Preferably, the method and the system of the present invention are capable of repetitive action, producing a series of high-power electromagnetic pulses.

As seen in FIG. 1, the 10 preferably comprises:
A flux compression generator 11 preferably comprising a tubular coil 12 in a magnetic field 13.
An optional source of electric power 14, preferably to generate the magnetic field 13 within the flux compression generator 11, for example if the magnetic field is provided by an electromagnet. Such power supplies are known in the art.
A source of pressure 15 to pressurize the tubular coil 12. Such pressure supplies are known in the art.
An optional pulse-conditioning device 16. An example of such pulse conditioner is provided in the Compact High Power Microwave document referenced in the Background chapter.
An antenna 17, such as a horn antenna, a parabolic (dish) antenna, a flat antenna, or a similar electromagnetic transducer. An example of such an antenna is provided in the Compact High Power Microwave document referenced in the Background chapter.

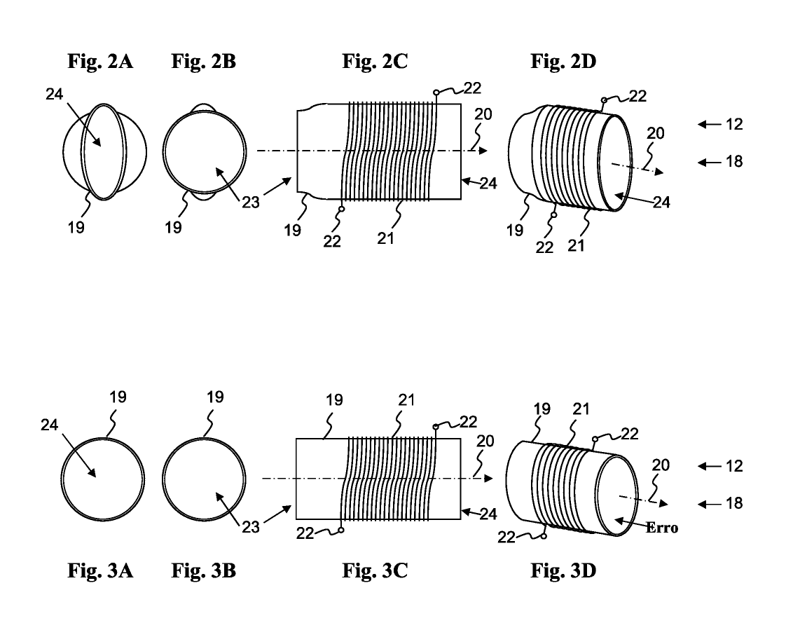

Reference is now made to FIGS. 2A, 2B, 2C and 2D, 3A, 3B, 3C and 3D and which are simplified illustrations of different views of a preferred implementation of the tubular coil 12 according to two preferred embodiments of the present invention. Preferably, the tubular coil 12 is an electromagnetic pulse generating apparatus or device.

FIGS. 2A, 2B, 2C and 2D are, respectively, output (rear), input (front), side and perspective views of an open-ended tubular coil 18 in a relaxed (or deflated) mode.

FIGS. 3A, 3B, 3C and 3D are, respectively, output (rear), input (front), side and perspective views of an open-ended tubular coil 18 in an inflated mode.

As seen in FIGS. 2A to 2D and 3A to 3D, the tubular coil 12 preferably comprises:
A flexible tube 19, preferably elongated along a first axis 20. Preferably, the tube 19 has an inflated mode as seen in FIGS. 3A, 3B, 3C and 3D and a non-inflated (deflated, relaxed) mode as seen in FIGS. 2A, 2B, 2C and 2D. Preferably, the cross section of the tube perpendicular to the first axis 20 is larger in the inflated mode than in the non-inflated mode. In the example of FIGS. 2A-2D the tube 19 in the deflated mode has the shape (cross-section) of an ellipsoid and the shape of a circle in the inflated mode.
An electrically conductive coil 21 wound along the first axis 20 and electrically connected to an output connector 22. The coil 21 can be embedded inside the tube 19 material, or wrapped around or inside the tube 19.

The tube 19 preferably comprises a first opening 23 (pressure input, front side) preferably connected to a source of hydraulic and/or pneumatic pressure. The tube 19 of the open-ended tubular coil 18 shown in FIGS. 2A to 2D and 3A to 3D preferably comprises a pressure output 24.

The tube 19 is preferably operative to receive a pulse of pressurised fluid, preferably from the pressure source 15 of FIG. 1. A pneumatic fluid is preferably gas, such as pressurized air or Nitrogen or any other gas, preferably gas that can be safely released to the atmosphere. A hydraulic fluid is preferably uncompressible fluid such as oil. Preferably, the fluid is present in the tube at all time, however, this is not mandatory.

Preferably, the pulse pressure causes the tube 19 to inflate. That is, affect a change of the form of the tube from the deflated mode as shown in FIGS. 2A to 2D to the inflated mode as shown in FIGS. 3A to 3D. The inflation affects a change of the cross-section area of the tube 19 and thus also affects a change of the cross-section of the coil 21. The coil is preferably placed in a magnetic field (or flux) at least partly perpendicular to the first axis 20 as shown in FIG. 1. The change of the cross-section area of the coil generated an electromagnetic pulse at the output connector 22. Alternatively, the magnetic field (or flux) at least partly perpendicular to the first axis 20 as will be described below.

Preferably, the tube 19 is made of a flexible material such as Nitinol, Nickel-Titanium composite, a shape memory alloy, a super-elastic material, etc.

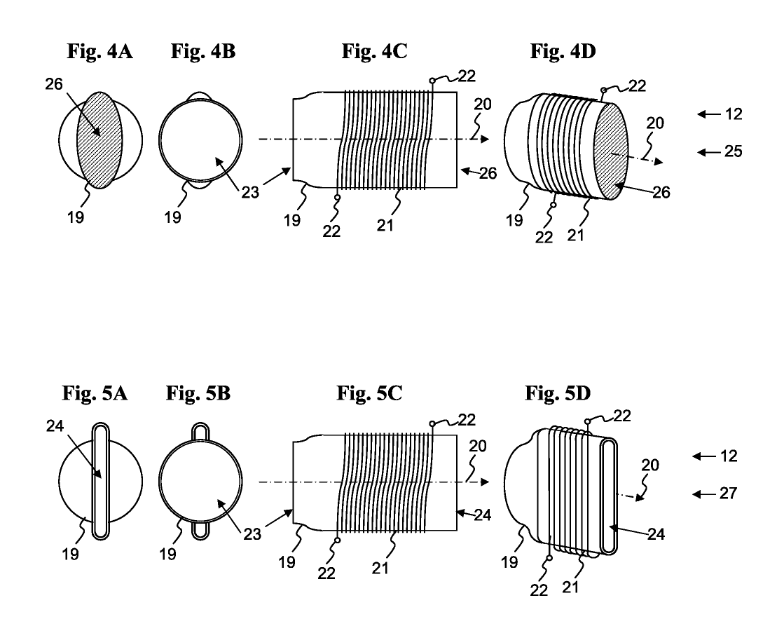

Reference is now made to FIGS. 4A, 4B, 4C, 4D which are simplified illustrations of different views of a closed-ended tubular coil 25, which is an alternative preferred implementation of the tubular coil 12 according to a preferred embodiment of the present invention.

The closed-ended tubular coil 25 is similar to the open-ended tubular coil 18 shown in FIGS. 2A to 2D and 3A to 3D except that the rear side 26 of the tube (opposite the input side) is closed. The closed-ended tubular coil 25 is preferably used with hydraulic pressure systems where the pressurized fluid is to be collected back to the pressure source 15 of FIG. 1.

Reference is now made to FIGS. 5A, 5B, 5C, 5D which are simplified illustrations of different views of a flat tubular coil 27, which is an alternative preferred implementation of the tubular coil 12 according to a preferred embodiment of the present invention.

The flat tubular coil 25 is similar to the open-ended tubular coil 18 shown in FIGS. 2A to 2D and 3A to 3D except that in the deflated mode the tube 19 is flat, while the cross-section of the tube 19 of the open-ended tubular coil 18 when in the deflated mode is oval or ellipsoid. Thus, the change of the area of the cross-section of the coil is larger in the flat tubular coil 25, generating a more powerful electromagnetic pulse.

The rear side 26 of the tube 19 of the flat tubular coil 25 is open like in the open-ended tubular coil 18. Alternatively and also preferably, the rear side of the tube 19 of the flat tubular coil 25 can be closed for use with hydraulic pressure systems.

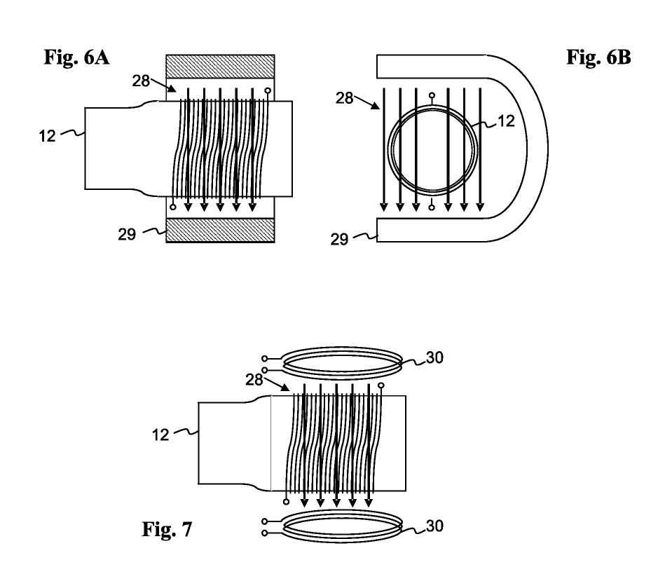

Reference is now made to FIGS. 6A and 6B, which are simplified illustrations of a side view and a front view, respectively, of the tubular coil 12 placed in a magnetic field 28 generated by a magnetic field generating device such as a fixed magnet 29, according to a preferred embodiment of the present invention.

It is appreciated that the tubular coil 12 of FIGS. 6A and 6B can be any of the open-ended tubular coil 18, the closed-ended tubular coil 25, or the flat tubular coil 25, or any similar configuration of the tubular coil 12.

Reference is now made to FIG. 7, which is a simplified illustrations of a side view of the tubular coil 12 placed in a magnetic field 28 generated a magnetic field generating device such as an electromagnet 30, according to a preferred embodiment of the present invention.

The electric power source 14 of FIG. 1 preferably powers the electromagnet 30, although any other adequate power-source may be considered.

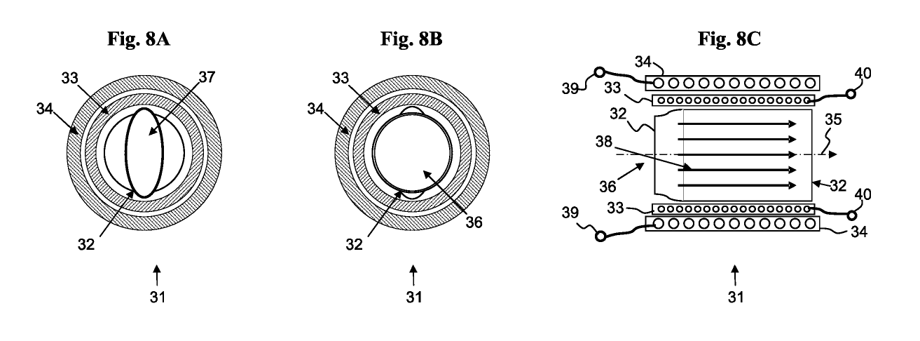

Reference is now made to FIGS. 8A, 8B and 8C, which are simplified schematic illustrations of an electromagnetic pulse generating device 31 according to a preferred embodiment of the present invention.

FIG. 8A is a back view of the electromagnetic pulse generating device 31, FIG. 8B is a front view of the electromagnetic pulse generating device 31, and FIG. 8C is a side cut through the electromagnetic pulse generating device 31.

As seen in FIGS. 8A, 8B, and 8C, the electromagnetic pulse generating device 31 preferably contains a conductive tube 32, an electrically conductive collector coil 33 and a magnetic field generating device 34.

The conductive tube is preferably flexible and elongated along axis 35. Preferably, the conductive tube 32 has an opening 36, which is preferably round, and an end 37 at the other side of the tube's body. The end 37 can be opened or closed. A closed end may include a deformable stopper preferably made of a polymer material. The conductive tube 32 has two modes: a deflated or unpressurized mode in which the cross-section of the conductive tube 32 (perpendicular to axis 35) is predominantly flat or oval, and an inflated or pressurized mode in which the cross-section of the conductive tube 32 is predominantly round. Preferably, the cross section of the conductive tube 32 perpendicular to the first axis 35 is larger in the inflated mode than in the deflated (non-inflated) mode.

The conductive tube 32 is similar in shape and function to the tube of the tubular coil 12, with the difference that the tube 32 comprises electrically conductive material or coating instead of the coil of the tubular coil 12. Both the tube of the tubular coil 12 and the tube of the conductive tube 32 can be referred to as Bourdon tube.

Preferably, the opening of the conductive tube 32 connects to a source of hydraulic and/or pneumatic pressure.

The magnetic-field generating device 34 preferably generates magnetic flux 38. Preferably but optionally, the magnetic-field generating device 34 is an electric coil and is positioned in parallel to the axis 35, thus producing magnetic field (or flux) 38 that is also parallel to axis 35. Preferably, the magnetic-field generating device 34 has an input connector 39 to receive electric current to generate the magnetic field 38.

The electrically conductive collector coil 33 is preferably wound along the first axis 35 and electrically connected to an output connector 40.

Preferably, the magnetic-field generating device 34, the collector coil 33 and the conductive tube 32 are positioned concentrically, as seen in FIGS. 8A, 8B, and 8C.

When the conductive tube 32 receives hydraulic and/or pneumatic pressure into the opening 36, the pressure causes the tube to inflate, the inflation causes change of the cross-section area of the conductive tube 32 within the magnetic flux, thus generating an electromagnetic pulse at the collector coil and its output connector 40.

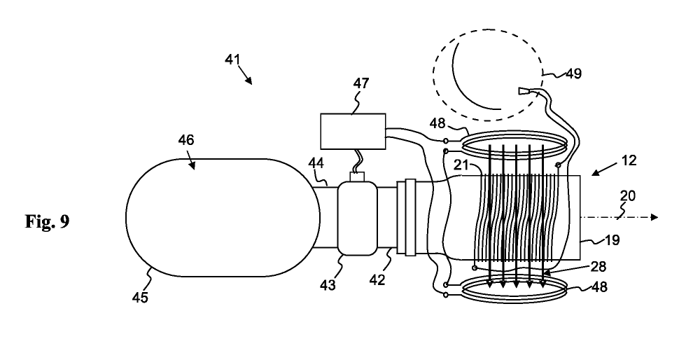

Reference is now made to FIG. 9, which is a simplified illustration of a side view of an electromagnetic pulse generator 41 according to a preferred embodiment of the present invention.

The electromagnetic pulse generator 41 preferably comprises a tubular coil 12 preferably comprising a tube 19 and a coil 21. The tube 19 preferably connected via a pipe 42 to a pressure valve 43 connected via a pipe 44 to a pressure reservoir 45 containing highly pressurized hydraulic or pneumatic fluid 46, preferably at about 3000 Bar. A controller 47 preferably controls the pressure valve to provide high-pressure pulse at the input opening of the tube 19. The controller 47 also preferably comprises an electric power supply to provide electric current to an electromagnet 48. The electromagnet 48 is preferably producing a magnetic field 28, preferably predominantly or at least partially perpendicular to a first axis 20 of the coil 21. The coil 21 is connected to an antenna 49 that may be, for example, parabolic (dish), or of any other adequate shape, or any other type of antenna.

To generate an electromagnetic pulse at the antenna 49, the controller 47 preferably provides electric current to the electromagnet 48 and synchronously opens the valve 47 to provide a pulse of highly pressurized fluid to the tubular coil 12. The pressurized fluid causes the tube 19 to expand from the deflated mode to the inflated mode, thus abruptly changing the cross-section area of the coil 21. Changing the cross-section area of the coil 21 in the magnetic field 28 produces an electromagnetic pulse at the output of the coil 21, which feeds to the antenna 49.

It is appreciated that preferably the electromagnetic pulse at the output of the coil 21 can be fed to the antenna 49 via a pulse-conditioning device such as device 16 of FIG. 1.

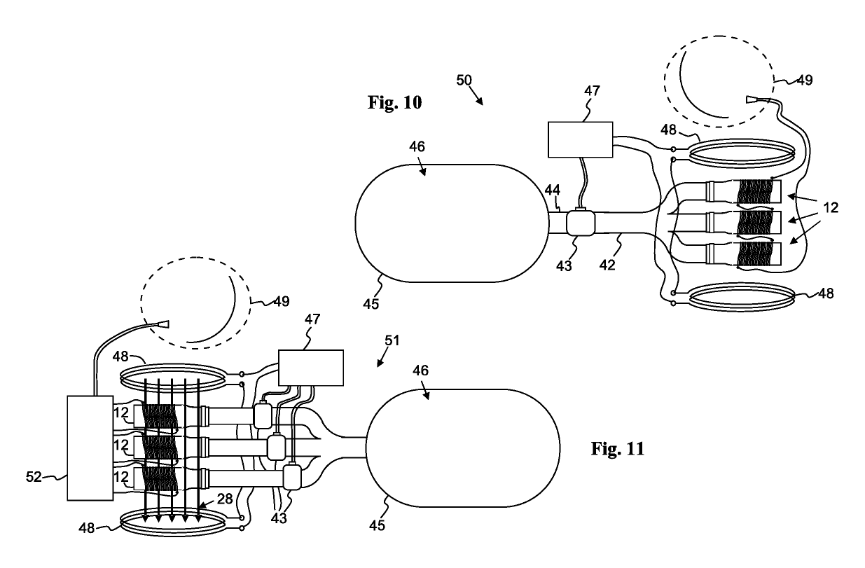

Reference is now made to FIG. 10, which is a simplified illustration of a side view of a multi-coil electromagnetic pulse generator 50 according to a preferred embodiment of the present invention.

As seen in FIG. 10, the multi-coil electromagnetic pulse generator 50 is similar to the electromagnetic pulse generator 41 except that it comprises a plurality of tubular coils 12. The multi-coil electromagnetic pulse generator 50 of FIG. 10 is an exemplary configuration that shows a plurality of tubular coils 12 that are connected to the antenna 49 in series to produce higher voltage pulse. Alternatively, connecting the plurality of tubular coils 12 in parallel to the antenna 49 would produce a higher current pulse. As an alternative option, the plurality of tubular coils 12 may be connected to the antenna 49 in a mixed configuration of serial and parallel connections. Alternatively, the electromagnet 48 of FIG. 10 can be replaced by a plurality of electromagnets, each surrounding a tubular coil 12.

It is appreciated that the electromagnetic pulse at the output of the coil 21 can be fed to the antenna 49 via a pulse-conditioning device such as device 16 of FIG. 1

In all the systems shown and described in accordance with FIGS. 9, 10, 11, and 12 (such as 41, 50, 51 and 53) the tubular coil 12 and its various configurations (such as 18, 25 and 27) can be replaced with the conductive tube 31 (and its similar configurations) with adequate changes to the field generating devices.

Reference is now made to FIG. 11, which is a simplified illustration of a side view of a separately-operated multi-coil electromagnetic pulse generator 51 according to a preferred embodiment of the present invention.

As seen in FIG. 11, the separately-operated multi-coil electromagnetic pulse generator 51 is similar to the multi-coil electromagnetic pulse generator 50 except that it comprises a plurality of pressure valves 43, thus enabling the controller 47 to pulse each of the tubular coils 12 independently of the others. Preferably, the controller 47 can simultaneously pulse any number of the plurality of tubular coils 12 to produce the desired intensity of the electromagnetic pulse at the antenna 49. Alternatively, the controller 47 can pulse any number of the plurality of tubular coils 12 synchronously to produce a closely packed series of electromagnetic pulses at the antenna 49.

In the exemplary configuration of the multi-coil electromagnetic pulse generator 51 of FIG. 11 the plurality of tubular coils 12 are connected to the antenna 49 in parallel via a pulse-conditioning device 52. Alternatively, the plurality of tubular coils 12 are connected to the antenna 49 in series. Also alternatively, the plurality of tubular coils 12 can be connected to the antenna 49 in a mixed configuration of serial and parallel connections. Alternatively, the electromagnet 48 of FIG. 11 can be a plurality of electromagnets, each surrounding a tubular coil 12.

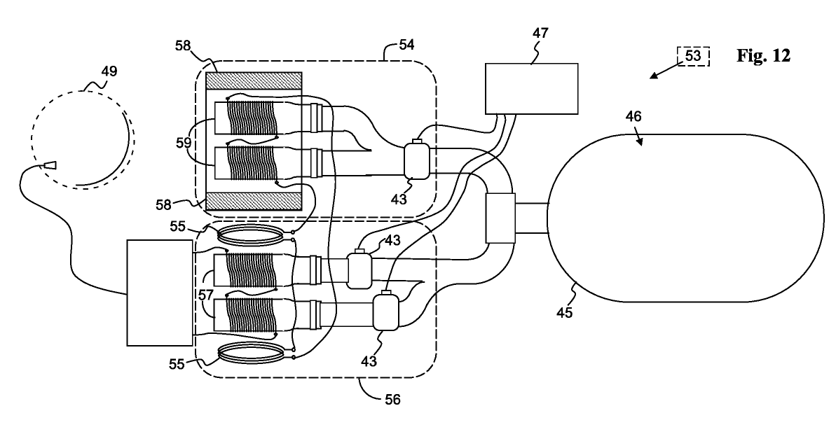

Reference is now made to FIG. 12, which is a simplified illustration of a side view of a pulse generator 53 according to a preferred embodiment of the present invention.

Pulse generator 53 preferably includes two stages where stage A (identified by numeral 54) generates a pulse of electric current for one or more electromagnets 55 of stage B (identified by numeral 56) to produce the electromagnetic field for tubular coils 57. Stage A preferably uses one or more fixed (iron) magnets 58 to produce the electromagnetic field for tubular coils 59. Controller 47 synchronizes the operation of the two stages, preferably by controlling pressure valves 43.

It is appreciated that the arrangement of the pressure valves 43 as shown in FIG. 12 for joint operation of the tubular coils (as shown for stage A) or separate operation of the tubular coils (as shown for stage B) is arbitrary and any suitable arrangement may be used.

It is appreciated that the arrangement of the tubular coils in series or in parallel is arbitrary and can be designed according to the requirements for current or voltage pulses.

It is appreciated that more than two stages can be used to reduce the number of tubular coils operated by fixed magnets.

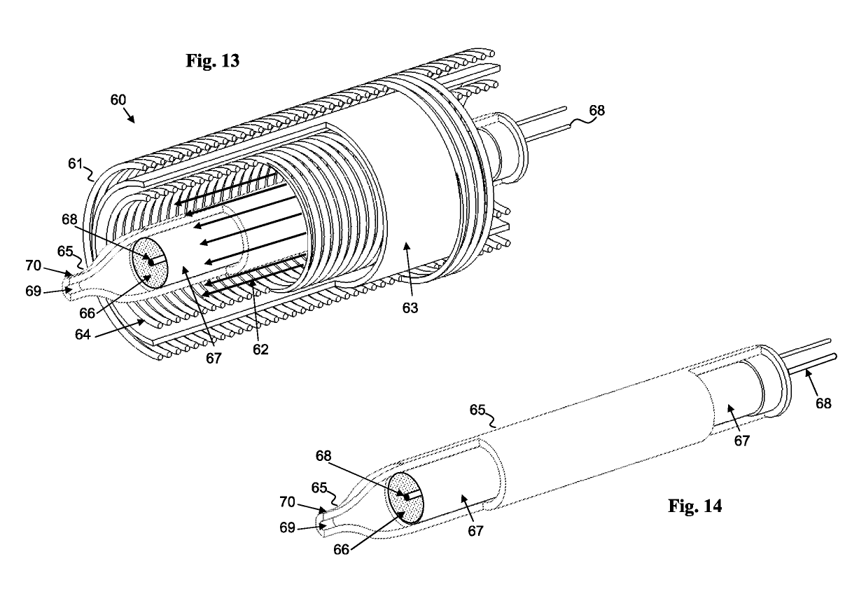

Reference is now made to FIG. 13, which is a simplified schematic illustration of an explosive electromagnetic pulse-generating device 60 and to FIG. 14, which is a simplified schematic illustration of a detail of the explosive electromagnetic pulse-generating device 60, according to a preferred embodiment of the present invention.

As seen in FIGS. 13 and 14, explosive electromagnetic pulse-generating device 60 preferably includes the following parts:
A first electrically-conductive coil 61 for generating magnetic field 62.
A housing 63 preferably placed within the first electrically conductive coil 61.
A second electrically-conductive coil (collector coil) 64 preferably placed within the housing 63 and operative to collect an electromagnetic pulse.
A flexible reaction barrel 65, preferably placed within the collector coil 64.
An explosive material 66, preferably contained in a cartridge 67, preferably placed within the reaction barrel 65.
An igniter (or a fuse) 68 placed within the explosive material 66.

The flexible reaction barrel 65 preferably contains, and/or is coated by, electrically conductive material. Barrel 65 is preferably operative to expand responsive to internal pressure, and to retract responsive to depletion of the internal pressure. Barrel 65 preferably includes an opening 69 through which the gases produces by the explosion of the explosive material 66 may exit. Preferably, barrel 64 also includes a stricture 70 about the opening 69 to control the amplitude and/or length of the pressure pulse.

To operate the explosive electromagnetic pulse-generating device 60 current is fed to the first electrically-conductive coil 61. Simultaneously, the igniter 68 is operated to detonate the explosive material 66. The explosion produces a pulse of pressure, which causes the barrel 65 to abruptly expand. This expansion produces an electromagnetic pulse that is collected by the collector coil 64.

Preferably, some or all of the parts of the explosive electromagnetic pulse-generating device 60 are placed concentrically.

Preferably, the barrel 65 enables replacement of the cartridge 67.

Preferably, the explosive material 66 contains aluminum and water, preferably as slurry, and the igniter 68 is a metal heating element. To detonate the aluminum and water slurry, electric current is fed to the igniter 68 to generate heat, typically at about 700 Celsius degrees.

The igniter 68 can be shaped as a metal rod, as a U-shaped metal rod, as a heating coil, etc. Current connectors can be provided at both ends of the igniter 68, or alternatively, at one end where the other end is grounded, for example, to the cartridge. Preferably, the igniter is placed along the entire length of the explosive material.

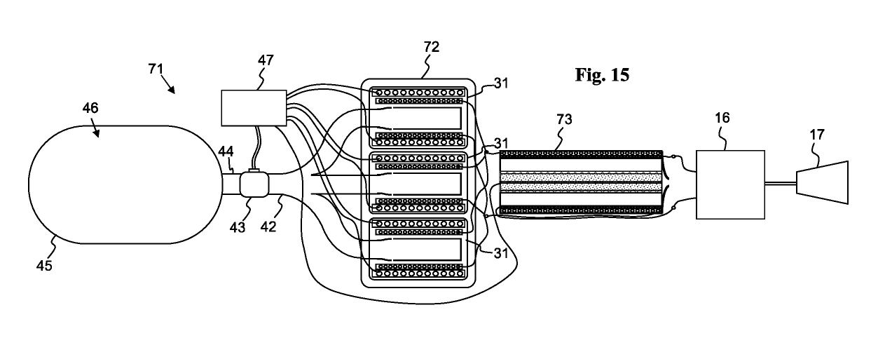

Reference is now made to FIG. 15, which is a simplified schematic illustration of an explosive pulse generating system 71 according to a preferred embodiment of the present invention.

The pulse generating system 71 preferably includes:
a pressure tank 45 preferably containing pressurized fluid 46;
a pipe system 44 and 42;
one or more pressure valves 43;
a controller 47;
a primary electric pulse generating device 72, preferably electrically operated by the controller 47, and connected to the pressure system via pipes 42;
a main electromagnetic pulse-generating device 73, preferably in the form of the explosive electromagnetic pulse-generating device 60 of FIG. 13;
optionally, a pulse conditioner 16; and
an antenna 17.

The primary electric pulse generating device 72 preferably contains one or more tubular coils 12 with their fixed magnets 31 or electromagnets 32, and/or one or more conductive tubes 31. FIG. 15 shows the primary electric pulse generating device 72 using conductive tubes 31.
Preferably, the collector coil(s) 33 of the conductive tubes 31 (or the coils of the tubular coils 12) are connected to the first electrically conductive coil 61 of the explosive electromagnetic pulse-generating device 60 (in the main electromagnetic pulse-generating device 73) and the collector coil 64 of the explosive electromagnetic pulse-generating device 60 is connected to the pulse conditioner 16 (or optionally directly to the antenna 17).

To operate the electromagnetic pulse generating system 71 the controller 47 feeds electric current to the conductive tubes 31 (or to the electromagnets of the tubular coils 12) and simultaneously opens one or more valves 43 to feed pressurized fluid the conductive tubes 31 (or to the tubular coils 12). The expansion of the conductive tubes 31 (or to the tubular coils 12) creates a pulse of electric current at the first electrically conductive coil 61 of the explosive electromagnetic pulse-generating device 60 (in the main electromagnetic pulse-generating device 73) which further creates a pulse of magnetic field inside the explosive electromagnetic pulse-generating device 60. Simultaneously, the controller 47 operates the igniter 68 to explode the explosive material within the explosive electromagnetic pulse-generating device 60. Thus, the barrel 65 expands and generates an electromagnetic pulse in the collector coil 64. This electromagnetic pulse is fed to the pulse conditioner 16 and hence to the antenna 17 (or optionally directly to the antenna 17).

It is appreciated that cooling may be applied to the tubular coils or to the conductive tubes to prevent over heating. Particularly, such cooling can be provided using pressurised Helium.

It is appreciated that for all the versions of the electromagnetic pulse generation systems shown and described in accordance with FIGS. 9, 10, 11, 12 and 15 these systems may use one or more tubular coil devices such as shown and described in accordance with FIGS. 2A-2D, 3A-3D, 4A-4D and 5A-5D, and/or one or more conductive tubes such as shown and described in accordance with FIGS. 13 and 14.

It is expected that during the life of this patent many relevant positioning devices and systems will be developed and the scope of the terms herein, is intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. An electromagnetic pulse generating apparatus comprising:
a flexible tube elongated along a first axis, said tube having an inflated mode and a non-inflated mode;
wherein a cross section of said tube perpendicular to said first axis is larger in said inflated mode than in said non-inflated mode;
wherein said tube comprises an electrically conductive coil wound along said first axis and electrically connected to an output connector; and
wherein said tube comprises an opening connected to a source of at least one of a hydraulic and pneumatic pressure;
a magnetic field generating apparatus providing magnetic flux;
wherein said tube is operative to receive said at least one of a hydraulic and pneumatic pressure into said opening, said pressure causing said tube to inflate, said inflation causing change of cross-section area of said coil within said magnetic flux, thus generating said electromagnetic pulse at said output connector.

2. An electromagnetic pulse generating apparatus comprising:
a flexible tube elongated along a first axis, said tube having an inflated mode and a non-inflated mode;
wherein a cross section of said tube perpendicular to said first axis is larger in said inflated mode than in said non-inflated mode;
wherein said tube comprises an electrically conductive material; and
wherein said tube comprises an opening connected to a source of at least one of a hydraulic and pneumatic pressure;
a magnetic field generating apparatus providing magnetic flux; and
an electrically conductive collector coil wound along said first axis and electrically connected to an output connector;
wherein said tube is operative to receive said at least one of a hydraulic and pneumatic pressure into said opening, said pressure causing said tube to inflate, said inflation causing change of cross-section area of said coil within said magnetic flux, thus generating said electromagnetic pulse at said collector coil.

3. An electromagnetic pulse generating apparatus according to claim 2 wherein said magnetic field is one of:
at least partially perpendicular to at least one of:
said first axis; and
a direction in which said change of area of said tube is maximal; and
at least partially perpendicular to said first axis.

4. An electromagnetic pulse generating apparatus according to claim 1 comprising a plurality of said flexible tubes.

5. An electromagnetic pulse generating apparatus according to claim 4 wherein said plurality of tubes comprising a plurality of coils connected to a common output connector in at least one of serial and parallel.

6. An electromagnetic pulse generating apparatus according to claim 1 wherein said flexible tube in said non-inflated mode is flat.

7. An electromagnetic pulse generating apparatus according to claim 1 wherein said cross-section of said flexible tube in said non-inflated mode forms the shape of an ellipse.

8. An electromagnetic pulse generating apparatus according to claim 1 wherein said cross-section of said flexible tube in said inflated mode forms the shape of a circle.

9. An electromagnetic pulse generating apparatus according to claim 1 wherein said magnetic field generating apparatus is at least one of a magnet and an electromagnet.

10. An electromagnetic pulse generating apparatus according to claim 1 wherein said flexible tube comprises at least one of Nitinol; a Nickel-Titanium composite: a shape memory alloy: and a super-elastic material.

11. An electromagnetic pulse generating system comprising:
an electromagnetic pulse generating apparatus according to claim 1 comprising; and
a pressure pulse generating apparatus;
wherein said output pressure connector of said pressure pulse generating apparatus is connected to said opening of said flexible tube of said electromagnetic pulse generating apparatus.

12. An electromagnetic pulse generating system according to claim 11 wherein said electromagnetic pulse generating apparatus comprises a plurality of said flexible tubes and wherein said pressure pulse generating apparatus is connected to said plurality of flexible tubes via a manifold.

13. An electromagnetic pulse generating system according to claim 12 and operative to deliver said pressure pulse to a selectable flexible tube.

14. An electromagnetic pulse generating system according to claim 12 and operative to deliver said pressure pulse simultaneously to a selectable group of flexible tubes.

15. An electromagnetic pulse generating system comprising:
a first electrically conductive coil operative to generate a magnetic field;
a housing placed within said first electrically conductive coil;
a second electrically conductive coil placed within said housing and operative to collect an electromagnetic pulse;
a reaction barrel comprising electrically conductive material, placed within said second electrically conductive coil, and operative to expand responsive to internal pressure, and to retract responsive to depletion of said internal pressure;
an explosive material placed within said reaction barrel; and
an igniter placed within said explosive material;
wherein said igniter is operative to detonate said explosive material; said explosive material producing a pulse of pressure; said pulse of pressure expanding said reaction barrel; said reaction barrel producing an electromagnetic pulse; said second electrically conductive collecting said electromagnetic pulse.

16. An electromagnetic pulse generating system according to claim 15 wherein said reaction barrel comprises an opening for releasing said pulse pressure;

17. An electromagnetic pulse generating system according to claim 16 wherein said opening for releasing said pulse pressure comprises a stricture;

18. An electromagnetic pulse generating system according to claim 15 wherein said explosive material is contained in a cartridge.

19. An electromagnetic pulse generating system according to claim 18 wherein said barrel and said cartridge are operative to enable replacement of said cartridge.

20. An electromagnetic pulse generating system according to claim 15 wherein said igniter is placed along said explosive material.

21. An electromagnetic pulse generating system according to claim 15 wherein at least two of said first electrically conductive coil, housing, second electrically conductive coil, reaction barrel, explosive material, and igniter are placed concentrically.

22. An electromagnetic pulse generating system according to claim 15 wherein said explosive material comprises aluminum and water.

23. An electromagnetic pulse generating system according to claim 11 wherein said output pressure connector is connected to said first electrically conductive coil and operative to generate a pulse of magnetic field.
